(19) United States
(12) Patent Application Publication
(10) Pub. No.: US 2018/0202071 A1
(43) Pub. Date: Jul. 19, 2018

(54) CRYSTAL STRUCTURE CONTROL METHOD AND HEAT TREATMENT METHOD

(71) Applicant: SCREEN HOLDINGS CO., LTD., Kyoto (JP)

(72) Inventors: Hikaru Kawarazaki, Kyoto (JP); Akitsugu Ueda, Kyoto (JP)

(21) Appl. No.: 15/851,252

(22) Filed: Dec. 21, 2017

(30) Foreign Application Priority Data
Jan. 13, 2017 (JP) 2017-003795

(51) Int. Cl. C30B 33/02; H01L 21/02; H01L 31/18; H01L 21/28; H01L 21/311

(52) U.S. Cl. CPC C30B 33/02; H01L 21/02381; H01L 21/02609; H01L 51/0545; H01L 21/28185; H01L 21/28194; H01L 21/31111; H01L 31/182

(57) ABSTRACT

A hafnium oxide film is deposited on a front surface of a substrate across a boundary layer film. By preheating the substrate on which the hafnium oxide film is formed, and then, irradiating the front surface of the substrate with intense flash light over an extremely short radiation time, only the front surface of the substrate is instantaneously heated and is rapidly thermally expanded. At this instant, a strong compressive stress is applied to the front surface of the substrate, and a tensile stress is applied to a back surface. By heating the hafnium oxide film and applying a strong compressive stress to the hafnium oxide film at the same time, the proportion of a cubic structure in a crystal structure of the hafnium oxide film can be increased, and the crystal structure occurring in the hafnium oxide film can be adjusted.

### BACKGROUND OF THE INVENTION

### Field of the Invention

The present invention relates to a crystal structure control method for controlling a crystal structure of a thin film formed on a surface of a thin-film precision electronic substrate (hereinafter simply referred to as “substrate”), such as a semiconductor wafer, and a heat treatment method.

### Description of the Background Art

Application of a high-k dielectric film (High-k film) of a material having a higher dielectric constant than a silicon dioxide (SiO₂), which is conventionally generally used, as a gate insulating film of a field effect transistor (FET) is being considered (for example, US2011/0081753). Development of a high-k dielectric film for a new stack structure, together with a metal gate electrode using metal for a gate electrode, is being advanced to solve a problem of a leak current which is increased as a gate insulating film is made thinner.

A hafnium-based material is promising as a high-k dielectric material, and a hafnium oxide (HfO₂) is one of potential candidates. The crystal structure of a hafnium oxide is a monoclinic structure under normal temperature and pressure. A material having a high dielectric constant is desirable as a high-k dielectric material, and a hafnium oxide having a cubic structure is known to have a higher dielectric constant than a hafnium oxide having the monoclinic structure. Accordingly, development of a high-k dielectric film formed of a hafnium oxide having the cubic structure is greatly desired.

### SUMMARY

The present invention is directed to a crystal structure control method for controlling a crystal structure of a thin film formed on a front surface of a substrate.

According to one aspect of the present invention, a crystal structure control method includes the steps of: (a) depositing a thin film on a front surface of a substrate, and (b) irradiating the front surface of the substrate with flash light from a flash lamp to heat the thin film and apply a compressive stress to the thin film.

A crystal structure occurring in the thin film deposited on the substrate can be adjusted such that the filling factor of crystal is increased.

Preferably, in the step (b), the compressive stress applied to the thin film is changed by adjusting a radiation time of the flash light.

The crystal structure appearing in the thin film deposited on the substrate can be appropriately adjusted.

The present invention is also directed to a heat treatment method for heating a substrate having a thin film formed on a front surface, and for controlling a crystal structure of the thin film.

According to one aspect of the present invention, a heat treatment method includes irradiating a front surface of the substrate with flash light from a flash lamp to heat the thin film and apply a compressive stress to the thin film.

Therefore, an object of the present invention is to adjust a crystal structure occurring in a thin film deposited on a substrate.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a vertical cross-sectional view illustrating a configuration of a heat treatment apparatus to be used in a crystal structure control method according to the present invention;

FIG. 2 is a perspective view illustrating an overall appearance of a retention unit;

FIG. 3 is a plan view of a susceptor;

FIG. 4 is a cross-sectional view of the susceptor;

FIG. 5 is a plan view of a transfer mechanism;

FIG. 6 is a side view of the transfer mechanism;

FIG. 7 is a plan view illustrating a layout of a plurality of halogen lamps;

FIG. 8 is a view illustrating a drive circuit of a flash lamp;

FIG. 9 is a view illustrating a substrate having a hafnium oxide thin film formed on a surface;

FIG. 10 is a view illustrating a behavior of the substrate at a time of flash light radiation; and

FIG. 11 is a view illustrating an X-ray diffraction pattern of a hafnium oxide film after flash heating.

### DESCRIPTION OF THE PREFERRED EMBODIMENT

Hereinafter, a preferred embodiment of the present invention will be described in detail with reference to the drawings.

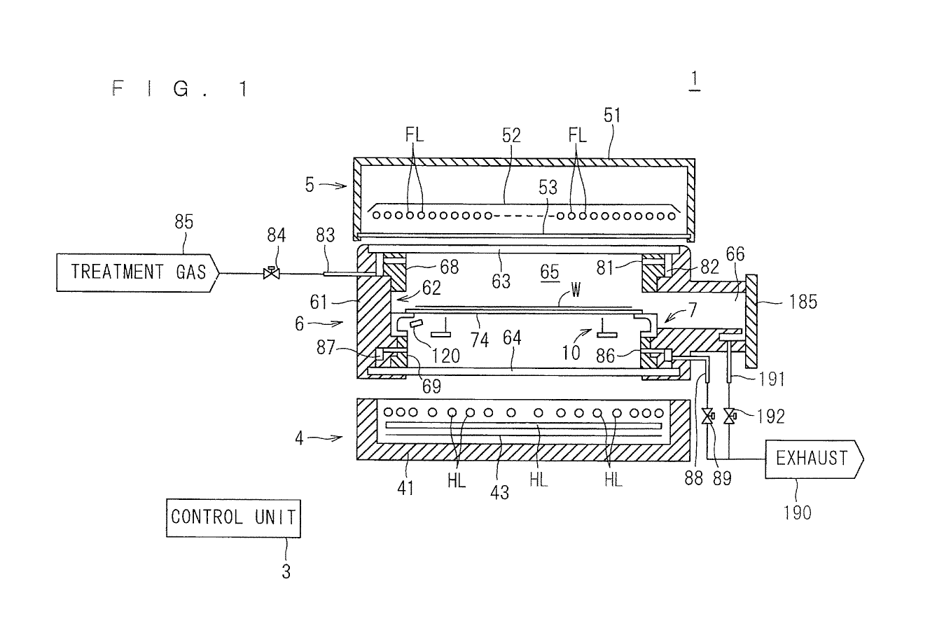

First, a heat treatment apparatus for performing heat treatment necessary to implement a crystal structure control method according to the present invention will be described. FIG. 1 is a vertical cross-sectional view illustrating a configuration of a heat treatment apparatus 1 to be used in the crystal structure control method according to the present invention. The heat treatment apparatus 1 in FIG. 1 is a flash lamp annealing apparatus for heating a disk-shaped substrate W by irradiating the substrate W with flash light. A size of the substrate W to be treated is not limited in particular, and it is ]300 mm or ϕ450 mm, for example. Furthermore, in FIG. 1 and following figures, a dimension of a component and the number of components are exaggerated or simplified as necessary so as to facilitate understanding.

The heat treatment apparatus 1 includes a chamber 6 for accommodating the substrate W, a flash heating unit 5 incorporating a plurality of flash lamps FL, and a halogen heating unit 4 incorporating a plurality of halogen lamps HL. The flash heating unit 5 is provided above the chamber 6, and the halogen heating unit 4 is provided below the chamber 6. Furthermore, in the chamber 6, the heat treatment apparatus 1 includes a retention unit 7 for horizontally retaining the substrate W, and a transfer mechanism 10 for transferring the substrate W between the retention unit 7 and an outside of the apparatus. Furthermore, the heat treatment apparatus 1 includes a control unit 3 for controlling each of operation mechanisms provided in the halogen heating unit 4, the flash heating unit 5, and the chamber 6 so as to perform heat treatment on the substrate W.

The chamber 6 is formed by attaching chamber windows made of quartz on upper and lower sides of a cylindrical chamber lateral part 61. The chamber lateral part 61 has a roughly cylindrical shape with open top and bottom, and an upper chamber window 63 is attached to close the upper opening and a lower chamber window 64 is attached to close the lower opening. The upper chamber window 63 forming a ceiling portion of the chamber 6 is a disk-shaped member made of quartz, and functions as a quartz window which transmits flash light emitted from the flash heating unit 5 into the chamber 6. Furthermore, the lower chamber window 64 forming a floor portion of the chamber 6 is also a disk-shaped member made of quartz, and functions as a quartz window which transmits light from the halogen heating unit 4 into the chamber 6.

Furthermore, a reflection ring 68 is attached to an upper portion of an inner wall surface of the chamber lateral part 61, and a reflection ring 69 is attached to a lower portion of the inner wall surface. Both the reflection rings 68, 69 are formed into an annular shape. The upper reflection ring 68 is attached by being fitted from an upper side of the chamber lateral part 61. The lower reflection ring 69 is attached by being fitted from a lower side of the chamber lateral part 61 and by being fixed by a screw (not shown). That is, both the reflection rings 68, 69 are detachably attached to the chamber lateral part 61. An inner space of the chamber 6, that is, a space surrounded by the upper chamber window 63, the lower chamber window 64, the chamber lateral part 61, and the reflection rings 68, 69 is defined as a heat treatment space 65.

When the reflection rings 68, 69 are attached to the chamber lateral part 61, a recessed part 62 is formed on the inner wall surface of the chamber 6. That is, the recessed part 62 is formed, which is surrounded by a center portion of the inner wall surface of the chamber lateral part 61 where the reflection rings 68, 69 are not attached, a lower end surface of the reflection ring 68, and an upper end surface of the reflection ring 69. The recessed part 62 is annularly formed on the inner wall surface of the chamber 6 along a horizontal direction, and surrounds the retention unit 7 for retaining the substrate W. The chamber lateral part 61 and the reflection rings 68, 69 are formed of a metal material (such as stainless steel) which is superior in strength and heat resistance.

Furthermore, a conveyance opening portion (furnace opening) 66 is formed in the chamber lateral part 61 to allow conveyance of the substrate W into and out of the chamber 6. The conveyance opening portion 66 can be opened and closed by a gate valve 185. The conveyance opening portion 66 is communicatively connected to an outer peripheral surface of the recessed part 62. Therefore, when the conveyance opening portion 66 is opened by the gate valve 185, the substrate W can be carried into the heat treatment space 65 from the conveyance opening portion 66 through the recessed part 62, and the substrate W can be carried out of the heat treatment space 65. Furthermore, when the conveyance opening portion 66 is closed by the gate valve 185, the heat treatment space 65 inside the chamber 6 becomes a hermetically sealed space.

Moreover, a gas supply hole 81 is formed in an upper portion of the inner wall of the chamber 6 to supply a treatment gas into the heat treatment space 65. The gas supply hole 81 is provided at a position higher than the recessed part 62 and may be provided in the reflection ring 68. The gas supply hole 81 is communicatively connected to a gas supplying pipe 83 through a buffer space 82 which is annularly formed inside a sidewall of the chamber 6. The gas supplying pipe 83 is connected to a treatment gas supply source 85. Furthermore, a valve 84 is interposed at a mid-portion of a path of the gas supplying pipe 83. When the valve 84 is opened, a treatment gas is supplied from the treatment gas supply source 85 into the buffer space 82. The treatment gas which has flowed into the buffer space 82 flows and spreads inside the buffer space 82 having a fluid resistance smaller than that of the gas supply hole 81, and is supplied into the heat treatment space 65 through the gas supply hole 81. For example, as the treatment gas, an inert gas such as nitrogen (N₂), a reactive gas such as hydrogen (H₂) or ammonia (NH₃), or a mixture gas thereof may be used (in the present preferred embodiment, a nitrogen gas is used).

A gas exhaust hole 86 is provided in a lower portion of the inner wall of the chamber 6 to exhaust gas inside the heat treatment space 65. The gas exhaust hole 86 is provided at a position lower than the recessed part 62, and may be provided in the reflection ring 69. The gas exhaust hole 86 is communicatively connected to a gas exhaust pipe 88 through a buffer space 87 which is annularly formed inside the sidewall of the chamber 6. The gas exhaust pipe 88 is connected to an exhaust unit 190. Furthermore, a valve 89 is inserted at a mid-portion of a path of the gas exhaust pipe 88. When the valve 89 is opened, gas inside the heat treatment space 65 is discharged from the gas exhaust hole 86 to the gas exhaust pipe 88 through the buffer space 87. Additionally, a plurality of gas supply holes 81 and a plurality of gas exhaust holes 86 may be provided along a circumferential direction of the chamber 6, and also, they may have a slit shape. Furthermore, the treatment gas supply source 85 and the exhaust unit 190 may be mechanisms provided in the heat treatment apparatus 1, or may be utilities in a factory where the heat treatment apparatus 1 is installed.

Furthermore, a gas exhaust pipe 191 is connected to a distal end of the conveyance opening portion 66 to discharge gas inside the heat treatment space 65. The gas exhaust pipe 191 is connected to the exhaust unit 190 through a valve 192. When the valve 192 is opened, gas inside the chamber 6 is exhausted through the conveyance opening portion 66.

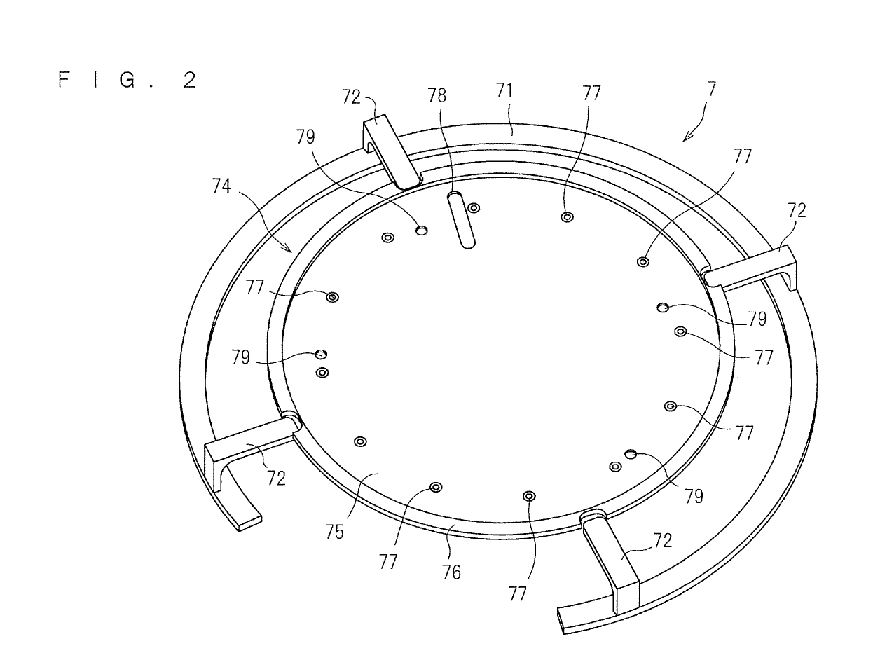

FIG. 2 is a perspective view illustrating an overall appearance of the retention unit 7. The retention unit 7 includes a base ring 71, coupling parts 72, and a susceptor 74. Each of the base ring 71, the coupling parts 72, and the susceptor 74 is formed of quartz. That is, the entire retention unit 7 is formed of quartz.

The base ring 71 is an arc-shaped quartz member with a part missing from an annular shape. This missing part is provided to prevent interference between transfer arms 11, described below, of the transfer mechanism 10 and the base ring 71. The base ring 71 is placed on a bottom surface of the recessed part 62 and is supported by the wall surface of the chamber 6 (see FIG. 1). A plurality of coupling parts 72 (four in the present preferred embodiment) are provided in a manner standing on an upper surface of the base ring 71 along the circumferential direction of the annular shape. The coupling parts 72 are also members made of quartz and are fixed to the base ring 71 by welding.

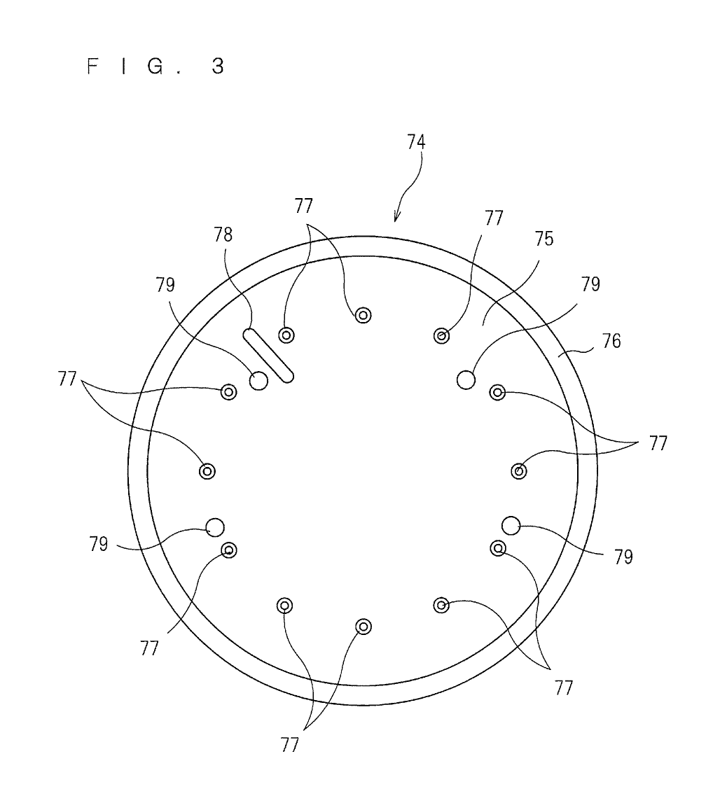

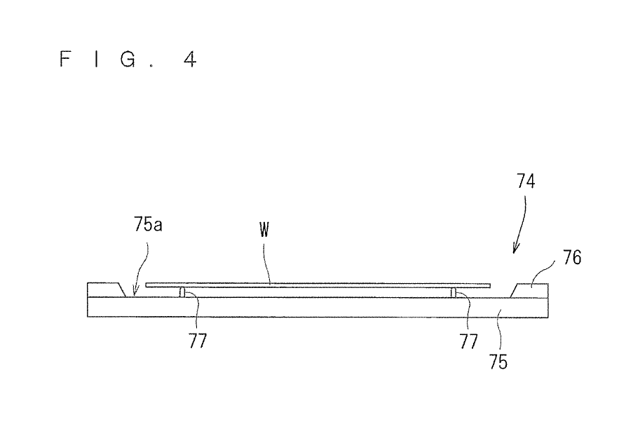

The susceptor 74 is supported by the four coupling parts 72 provided on the base ring 71. FIG. 3 is a plan view of the susceptor 74. FIG. 4 is a cross-sectional view of the susceptor 74. The susceptor 74 includes a retention plate 75, a guide ring 76, and a plurality of substrate support pins 77. The retention plate 75 is a roughly circular plate-shaped member formed of quartz. A diameter of the retention plate 75 is larger than a diameter of the substrate W. That is, the retention plate 75 has a planar size larger than the substrate W.

The guide ring 76 is installed on an upper-surface peripheral portion of the retention plate 75. The guide ring 76 is an annular member having an inner diameter larger than the diameter of the substrate W. For example, if the diameter of the substrate W is ϕ300 mm, the inner diameter of the guide ring 76 is ϕ320 mm. An inner circumference of the guide ring 76 is formed into a tapered surface which is enlarged upward from the retention plate 75. The guide ring 76 is formed of quartz similarly to the retention plate 75. The guide ring 76 may be welded to an upper surface of the retention plate 75, or may be fixed to the retention plate 75 with a separately processed pin, for example. Alternatively, the retention plate 75 and the guide ring 76 may be processed as one integrated member.

A region, of the upper surface of the retention plate 75, that is on the inside of the guide ring 76 serves as a planar retention surface 75a for retaining the substrate W. The plurality of substrate support pins 77 are provided in a manner standing on the retention surface 75a of the retention plate 75. In the present preferred embodiment, a total of twelve substrate support pins 77 are provided in a manner standing on the retention surface 75a at every 30 degrees along a circumference of a circle concentric with an outer circumference circle of the retention surface 75a (inner circumferential circle of the guide ring 76). A diameter of the circle on which the twelve substrate support pins 77 are disposed (a distance between opposite substrate support pins 77) is smaller than the diameter of the substrate W, and is between 270 mm and ϕ280 mm (ϕ270 mm in the present preferred embodiment) when the diameter of the substrate W is ϕ300 mm. Each of the substrate support pins 77 is formed of quartz. The plurality of substrate support pins 77 may be provided on the upper surface of the retention plate 75 by welding, or may be integrally processed with the retention plate 75.

Referring back to FIG. 2, the four coupling parts 72 provided in a manner standing on the base ring 71 are fixed to the peripheral portion of the retention plate 75 of the susceptor 74 by welding. That is, the susceptor 74 and the base ring 71 are fixedly coupled to each other by the coupling parts 72. The retention unit 7 is attached to the chamber 6 by the base ring 71 of the retention unit 7 being supported by the wall surface of the chamber 6. In a state where the retention unit 7 is attached to the chamber 6, the retention plate 75 of the susceptor 74 is horizontally maintained (with a normal line coinciding with a vertical direction). That is, the retention surface 75a of the retention plate 75 is made a horizontal surface.

The substrate W carried into the chamber 6 is placed and retained in a horizontal state on the susceptor 74 of the retention unit 7 attached to the chamber 6. At this time, the substrate W is retained by the susceptor 74 by being supported by the twelve substrate support pins 77, which are provided in a manner standing on the retention plate 75. More precisely, upper end portions of the twelve substrate support pins 77 come into contact with a lower surface of the substrate W to support the substrate W. Since heights of the twelve substrate support pins 77 (distances from the upper ends of the substrate support pins 77 to the retention surface 75a of the retention plate 75) are uniform, the substrate W can be horizontally supported by the twelve substrate support pins 77.

The substrate W is supported by the plurality of substrate support pins 77 with a predetermined gap to the retention surface 75a of the retention plate 75. A thickness of the guide ring 76 is greater than the height of the substrate support pins 77. Therefore, the substrate W supported by the plurality of substrate support pins 77 is prevented by the guide ring 76 from being shifted in the horizontal direction.

Furthermore, as illustrated in FIGS. 2 and 3, a vertically penetrating opening portion 78 is formed in the retention plate 75 of the susceptor 74. The opening portion 78 is provided so that a radiation thermometer 120 (see FIG. 1) can receive radiation light (infrared light) emitted from the lower surface of the substrate W retained by the susceptor 74. That is, the radiation thermometer 120 receives light emitted from the lower surface of the substrate W retained by the susceptor 74 through the opening portion 78, and a temperature of the substrate W is measured by a separately installed detector. Furthermore, four through holes 79 are formed in the retention plate 75 of the susceptor 74 so as to allow penetration of lift pins 12 of the transfer mechanism 10, described below, for transfer of the substrate W.

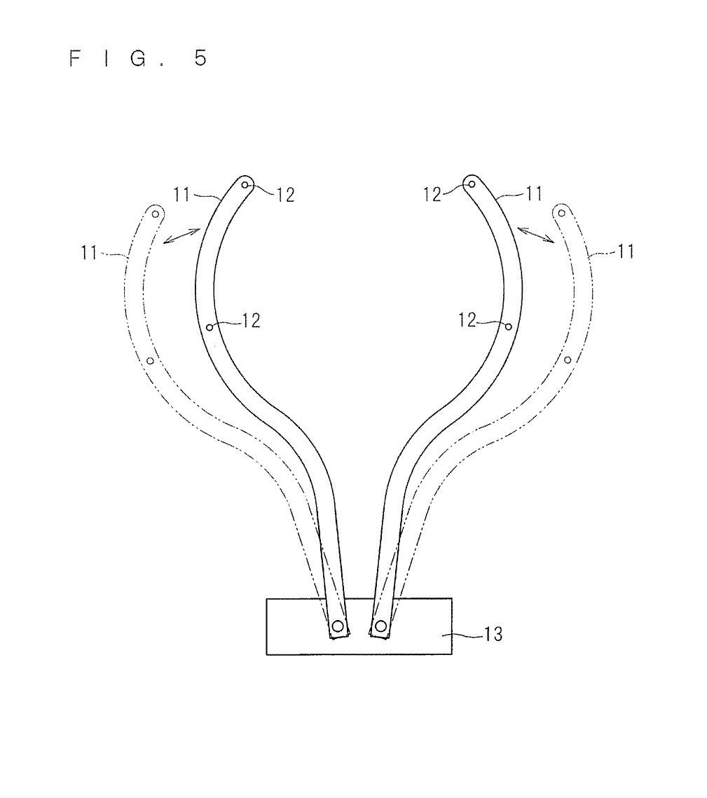

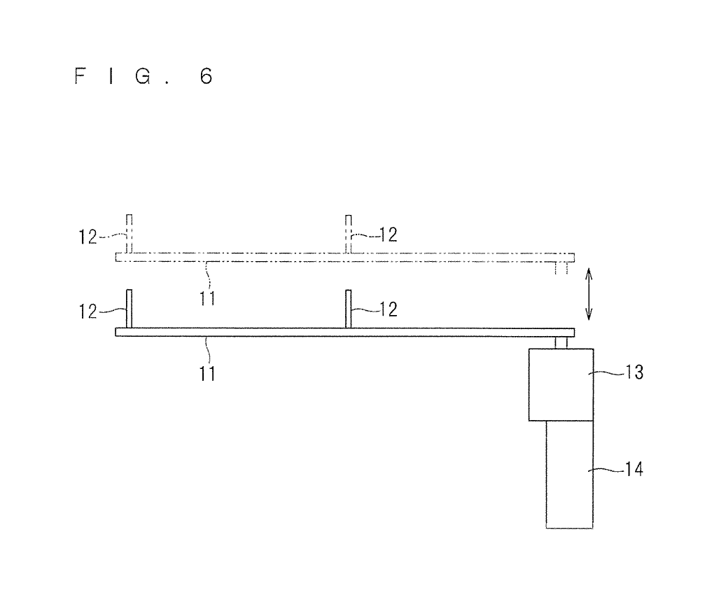

FIG. 5 is a plan view of the transfer mechanism 10. FIG. 6 is a side view of the transfer mechanism 10. The transfer mechanism 10 includes two transfer arms 11. The transfer arms 11 have an arc shape which is along an approximately annular recessed part 62. Two lift pins 12 are provided on each of the transfer arms 11 in a standing manner. Each transfer arm 11 can be pivotably moved by a horizontal movement mechanism 13. The horizontal movement mechanism 13 horizontally moves the pair of transfer arms 11 between a transfer operation position (solid-line position in FIG. 5) at which the substrate W is transferred to the retention unit 7 and a retreat position (two-dot chain line in FIG. 5) at which the transfer arms 11 do not overlap with the substrate W retained by the retention unit 7 in plan view. The horizontal movement mechanism 13 may separately turn the transfer arms 11 by respective motors, or may turn the pair of transfer arms 11 in conjunction with each other by one motor using a link mechanism.

Furthermore, the pair of transfer arms 11 is vertically moved together with the horizontal movement mechanism 13 by an elevating mechanism 14. When the elevating mechanism 14 raises the pair of transfer arms 11 at the transfer operation position, the total four lift pins 12 pass through the through holes 79 (see FIGS. 2 and 3) piercing the susceptor 74, and upper ends of the lift pins 12 project from an upper surface of the susceptor 74. Meanwhile, when the elevating mechanism 14 lowers the pair of transfer arms 11 at the transfer operation position, the lift pins 12 are removed from the through holes 79, and then the horizontal movement mechanism 13 moves the pair of transfer arms 11 to open, the transfer arms 11 are each moved to the retreat position. The retreat position of the pair of transfer arms 11 is right above the base ring 71 of the retention unit 7. Since the base ring 71 is placed on the bottom surface of the recessed part 62, the retreat position of the transfer arms 11 is inside the recessed part 62. Additionally, an exhaust mechanism (not shown) is provided also in the vicinity of a part where the drive unit (the horizontal movement mechanism 13 and the elevating mechanism 14) of the transfer mechanism 10 is provided so as to discharge atmosphere around the drive unit of the transfer mechanism 10 to outside the chamber 6.

Referring back to FIG. 1, the flash heating unit 5 provided above the chamber 6 includes, inside a housing 51, a light source including a plurality of (30 in the present preferred embodiment) xenon flash lamps FL, and a reflector 52 provided to cover the light source from above. Furthermore, a lamp-light radiation window 53 is attached to a bottom portion of the housing 51 of the flash heating unit 5. The lamp-light radiation window 53 constituting a floor portion of the flash heating unit 5 is a plate-shaped quartz window formed of quartz. Because the flash heating unit 5 is provided above the chamber 6, the lamp-light radiation window 53 faces the upper chamber window 63. The flash lamps FL emit flash light from above the chamber 6 to the heat treatment space 65 through the lamp-light radiation window 53 and the upper chamber window 63.

Each of the plurality of flash lamps FL is a rod-shaped lamp having a long cylindrical shape, and the lamps are arranged in a planar manner such that longitudinal directions of the lamps become parallel to each other over a main surface of the substrate W retained by the retention unit 7 (that is, along the horizontal direction). Thus, a planar surface formed by the arranged flash lamps FL is also a horizontal surface.

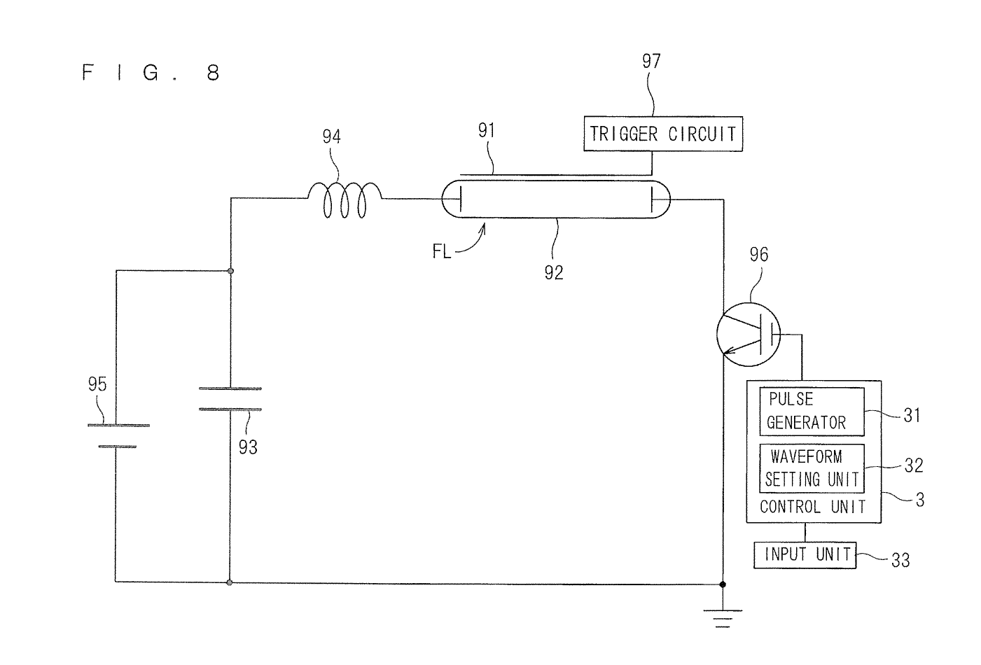

FIG. 8 is a view illustrating a drive circuit of the flash lamp FL. As illustrated in FIG. 8, a capacitor 93, a coil 94, the flash lamp FL, and an insulated gate bipolar transistor (IGBT) 96 are connected in series. Furthermore, as illustrated in FIG. 8, the control unit 3 includes a pulse generator 31 and a waveform setting unit 32, and is connected to an input unit 33. As the input unit 33, various well-known input devices such as a keyboard, a mouse, and a touch panel may be adopted. The waveform setting unit 32 sets a waveform of a pulse signal based on input contents from the input unit 33, and the pulse generator 31 generates a pulse signal based on the waveform.

The flash lamp FL includes a rod-shaped glass tube (discharge tube) 92 containing sealed xenon gas and having an anode and a cathode at both ends, and a trigger electrode 91 provided above an outer circumferential surface of the glass tube 92. A predetermined voltage is applied to the capacitor 93 from a power supply unit 95, and charge corresponding to the applied voltage (charge voltage) is accumulated therein. Moreover, a high voltage can be applied to the trigger electrode 91 from a trigger circuit 97. The timing for applying the voltage from the trigger circuit 97 to the trigger electrode 91 is controlled by the control unit 3.

The IGBT 96 is a bipolar transistor incorporating a metal oxide semiconductor field effect transistor (MOSFET) in a gate portion, and is a switching element suitable for handling large power. A pulse signal is applied to the gate of the IGBT 96 from the pulse generator 31 of the control unit 3. When a voltage of a predetermined value or higher (i.e. high voltage) is applied to the gate of the IGBT 96, the IGBT 96 is placed in an on-state, and when a voltage of a value lower than the predetermined value (i.e. low voltage) is applied, the IGBT 96 is placed in an off-state. The drive circuit including the flash lamp FL is thereby turned on/off by the IGBT 96. When the IGBT 96 is turned on/off, the flash lamp FL is connected to or disconnected from the corresponding capacitor 93, and a current flowing to the flash lamp FL is subjected to on/off control.

Even when the IGBT 96 is placed in the on-state and a high voltage is applied to the electrodes on both ends of the glass tube 92 in a state where the capacitor 93 is charged, electricity does not flow inside the glass tube 92 in a normal state because xenon gas is an electrical insulator. However, in a case where a high voltage is applied to the trigger electrode 91 from the trigger circuit 97 to cause insulation breakdown, a current instantaneously flows inside the glass tube 92 due to discharge between the electrodes on both ends, and light is emitted due to excitation of atoms or molecules of xenon.

The drive circuit illustrated in FIG. 8 is individually provided for each of the plurality of flash lamps FL provided in the flash heating unit 5. In the present preferred embodiment, the 30 flash lamps FL are arranged in a planar manner, and 30 drive circuits as illustrated in FIG. 8 are correspondingly provided. Thus, current flowing in each of the 30 flash lamps FL is subjected to individual on/off control by the corresponding IGBT 96.

Furthermore, the reflector 52 is provided above the plurality of flash lamps FL so as to entirely cover the lamps. A basic function of the reflector 52 is to reflect flash light emitted from the flash lamps FL toward the heat treatment space 65. The reflector 52 is formed of an aluminum alloy plate, and a surface roughening process is performed on its surface (surface facing the flash lamps FL) by blast treatment.

The halogen heating unit 4 provided below the chamber 6 incorporates the plurality of (40 in the present preferred embodiment) halogen lamps HL in a housing 41. The halogen heating unit 4 is a light radiation unit for irradiating the heat treatment space 65 with light from below the chamber 6 through the lower chamber window 64 by the plurality of halogen lamps HL to thereby heat the substrate W.

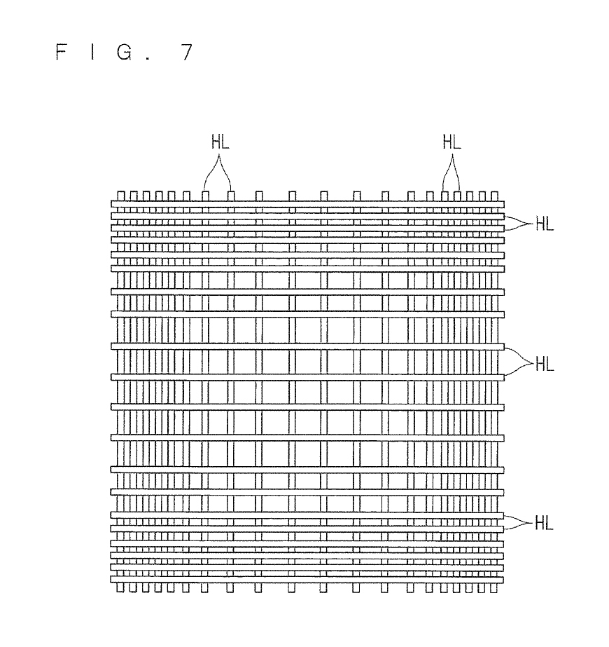

FIG. 7 is a plan view illustrating a layout of the plurality of halogen lamps HL. The 40 halogen lamps HL are disposed separately in two stages of upper and lower stages. Twenty halogen lamps HL are disposed in the upper stage close to the retention unit 7, and 20 halogen lamps HL are disposed in the lower stage farther from the retention unit 7 than the upper stage. Each halogen lamp HL is a rod-shaped lamp having a long cylindrical shape. The 20 halogen lamps HL in each of the upper stage and the lower stage are arranged in such a way that their longitudinal directions are parallel to each other over the main surface of the substrate W retained by the retention unit 7 (that is, along the horizontal direction). Thus, a planar surface formed by the arranged halogen lamps HL in each of the upper and lower stages is a horizontal surface.

Furthermore, as illustrated in FIG. 7, in both the upper and lower stages, a density of the disposed halogen lamps HL is higher in a region facing a peripheral portion of the substrate W retained by the retention unit 7 than in a region facing a center portion of the substrate W. That is, in both the upper and lower stages, a pitch of the disposed halogen lamps HL is smaller in a peripheral portion of the lamp arrangement than in a center portion thereof. Therefore, irradiation with a larger amount of light can be performed on the peripheral portion of the substrate W where temperature reduction is easily caused at a time of heating by light radiation from the halogen heating unit 4.

Furthermore, a lamp group composed of the halogen lamps HL in the upper stage and a lamp group composed of the halogen lamps HL in the lower stage are arranged to intersect with each other in the form of a lattice. That is, a total of 40 halogen lamps HL are arranged in such a manner that the longitudinal direction of the 20 halogen lamps HL arranged in the upper stage intersects with the longitudinal direction of the 20 halogen lamps HL arranged in the lower stage.

The halogen lamp HL is a filament-type light source which emits light by causing a filament disposed in the glass tube to be incandescent by distributing electricity to the filament. Inside the glass tube, a gas obtained by introducing a minute amount of halogen element (such as iodine or bromine) to an inert gas such as nitrogen or argon is sealed. As a result of introducing the halogen element, the temperature of the filament can be set to a high temperature while preventing breaking of the filament. Therefore, the halogen lamp HL has characteristics that, compared with a normal incandescent lamp, the life is longer and intense light can be continuously radiated. That is, the halogen lamp HL is a continuously lighting lamp which continuously emits light for at least one second. Furthermore, since the halogen lamp HL is a rod-shaped lamp, it has a long life, and when the halogen lamps HL are disposed along the horizontal direction, a radiation efficiency to the substrate W provided above can be excellent.

Also in the housing 41 of the halogen heating unit 4, a reflector 43 is provided below the two-stage halogen lamps HL (see FIG. 1). The reflector 43 reflects light emitted from the plurality of halogen lamps HL toward the heat treatment space 65.

The control unit 3 controls the above-described various operation mechanisms provided in the heat treatment apparatus 1. A configuration of the control unit 3 as hardware is similar to that of a general computer. That is, the control unit 3 includes a CPU serving as a circuit for performing various types of arithmetic processing, a ROM serving as a read-only memory for storing a basic program, a RAM serving as a readable/writable memory for storing various pieces of information, and a magnetic disk for storing software for control, data and the like. Processing at the heat treatment apparatus 1 proceeds due to execution of a predetermined processing program by the CPU of the control unit 3. Moreover, as illustrated in FIG. 8, the control unit 3 includes the pulse generator 31 and the waveform setting unit 32. As described above, the waveform setting unit 32 sets a waveform of a pulse signal based on input contents from the input unit 33, and the pulse generator 31 outputs a pulse signal to the gate of the IGBT 96 based on the waveform.

Other than the above-described configurations, the heat treatment apparatus 1 includes various cooling structures to prevent temperatures of the halogen heating unit 4, the flash heating unit 5, and the chamber 6 from being excessively increased due to thermal energy generated by the halogen lamps HL and flash lamps FL during the heat treatment for the substrate W. For example, a water-cooled tube (not illustrated) is provided in a wall of the chamber 6. Furthermore, each of the halogen heating unit 4 and the flash heating unit 5 is an air-cooling structure which forms a gas flow inside it to exhaust heat. Furthermore, gas is supplied to a gap between the upper chamber window 63 and the lamp-light radiation window 53 to cool the flash heating unit 5 and the upper chamber window 63.

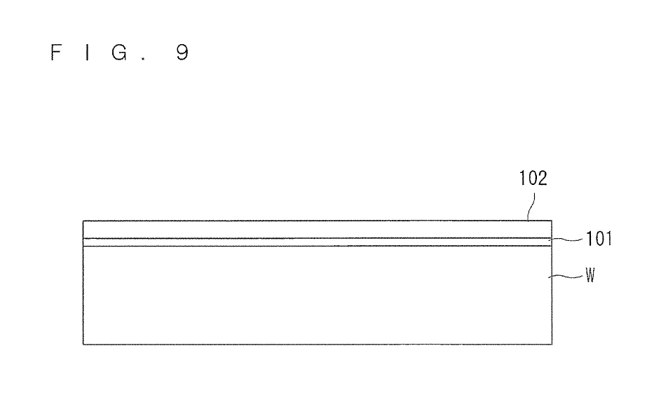

Next, the crystal structure control method according to the present invention will be described. First, a hafnium oxide (HfO₂) thin film is deposited on a surface of the substrate W. FIG. 9 is a view illustrating the substrate W having a hafnium oxide thin film formed on a surface. For example, the substrate W is a disk-shaped semiconductor wafer of silicon. A boundary layer film 101 of silicon dioxide (SiO₂) as a base for the hafnium oxide thin film is deposited on the surface of the substrate W by a method such as a thermal oxidation method. The boundary layer film 101 has a thickness of 0.8 nm, for example.

A hafnium oxide thin film 102 (hereinafter referred to as “hafnium oxide film 102”) is deposited on the boundary layer film 101. The hafnium oxide film 102 is deposited by accumulating a hafnium oxide, which is a high-k dielectric material, on the boundary layer film 101 by an atomic layer deposition (ALD) method, for example. A thickness of the hafnium oxide film 102 that is accumulated on the boundary layer film 101 is 3 nm, for example. The method for forming the hafnium oxide film 102 is not limited to ALD, and a known method such as metal organic chemical vapor deposition (MOCVD) may be adopted, for example.

The hafnium oxide film 102 immediately after deposition does not have a specific crystal structure, and is close to being in an amorphous state. In a case where the hafnium oxide thin film is formed as a high-k dielectric gate insulating film of a field effect transistor, typically, the hafnium oxide thin film is caused to have a crystal structure by post deposition annealing (PDA).

In the present preferred embodiment, flash heating is performed on the substrate W having the hafnium oxide film 102 formed on the surface, by radiation of flash light using the heat treatment apparatus 1. In the following, processing of the substrate W by the heat treatment apparatus 1 will be described. A processing procedure of the heat treatment apparatus 1 described below proceeds by the control unit 3 controlling each operation mechanism of the heat treatment apparatus 1.

First, the gate valve 185 is opened and the conveyance opening portion 66 is opened, and the substrate W on which the hafnium oxide film 102 is formed is carried by a carrier robot provided outside the apparatus into the heat treatment space 65 inside the chamber 6 through the conveyance opening portion 66. At this time, flow of an atmosphere outside the apparatus into the chamber 6 may be suppressed to a minimum by continuously supplying a nitrogen gas into the chamber 6 and causing a nitrogen gas flow to flow out through the conveyance opening portion 66. The substrate W carried in by the carrier robot is moved to a position immediately above the retention unit 7, and is stopped. Then, the pair of transfer arms 11 of the transfer mechanism 10 is horizontally moved from the retreat position to the transfer operation position and is raised, and the lift pins 12 are projected from the upper surface of the retention plate 75 of the susceptor 74 through the through holes 79 to receive the substrate W. Here, the lift pins 12 are raised to be higher than the upper ends of the substrate support pins 77.

After the substrate W is placed on the lift pins 12, the carrier robot exits from the heat treatment space 65, and the conveyance opening portion 66 is closed by the gate valve 185. Then, the pair of transfer arms 11 is lowered, and the substrate W is transferred from the transfer mechanism 10 to the susceptor 74 of the retention unit 7 and is horizontally retained from below. The substrate W is retained by the susceptor 74 while being supported by the plurality of substrate support pins 77 provided in a manner standing on the retention plate 75. Moreover, the substrate W is retained by the retention unit 7 with the front surface where the hafnium oxide film 102 is formed as an upper surface. A predetermined gap is formed between a back surface (a main surface opposite the front surface) of the substrate W supported by the plurality of substrate support pins 77 and the retention surface 75a of the retention plate 75. The pair of transfer arms 11 lowered below the susceptor 74 is caused by the horizontal movement mechanism 13 to retreat to the retreat position, that is, inside the recessed part 62.

Furthermore, after the conveyance opening portion 66 is closed by the gate valve 185 and the heat treatment space 65 is made a hermetically sealed space, an atmosphere in the chamber 6 is adjusted. More specifically, the valve 84 is opened, and a treatment gas is supplied from the gas supply hole 81 into the heat treatment space 65. In the present preferred embodiment, a nitrogen gas (N₂) is supplied as a treatment gas into the heat treatment space 65 inside the chamber 6. Furthermore, the valve 89 is opened, and the gas in the chamber 6 is exhausted from the gas exhaust hole 86. Thus, the treatment gas supplied from an upper part of the heat treatment space 65 inside the chamber 6 flows downward and is exhausted from a lower part of the heat treatment space 65, and the atmosphere inside the heat treatment space 65 is replaced with nitrogen. Furthermore, when the valve 192 is opened, the gas inside the chamber 6 is exhausted also through the conveyance opening portion 66. Furthermore, the atmosphere around the drive unit of the transfer mechanism 10 is also exhausted through an exhaust mechanism (not shown).

After the atmosphere in the chamber 6 is replaced with nitrogen, and the substrate W is horizontally retained by the susceptor 74 of the retention unit 7 from below, the 40 halogen lamps HL of the halogen heating unit 4 are turned on at the same time, and preheating (assist heating) of the substrate W is started. Halogen light emitted from the halogen lamps HL is radiated on the back surface of the substrate W through the lower chamber window 64 and the susceptor 74 made of quartz. The substrate W is preheated by receiving the light radiated by the halogens lamps HL, and is increased in temperature. Additionally, the transfer arms 11 of the transfer mechanism 10 are retreated inside the recessed part 62, and therefore, do not hinder the preheating by the halogen lamps HL.

While the preheating by the halogen lamps HL is being performed, the temperature of the substrate W is measured by the radiation thermometer 120. That is, the increasing temperature of the substrate is measured by the radiation thermometer 120 receiving infrared light emitted, through the opening portion 78, from the back surface of the substrate W retained by the susceptor 74. The measured temperature of the substrate W is transmitted to the control unit 3. The control unit 3 controls output of the halogen lamps HL while monitoring whether or not the temperature of the substrate W rising due to light irradiation from the halogen lamps HL has reached a predetermined preheating temperature T1. That is, the control unit 3 performs feedback control of the output of the halogen lamps HL based on a measurement value of the radiation thermometer 120 so that the temperature of the substrate W reaches the preheating temperature T1. In the present preferred embodiment, the preheating temperature T1 is 500° C.

After the temperature of the substrate W reached the preheating temperature T1, the control unit 3 keeps the substrate W at the preheating temperature T1 for a while. More specifically, when the temperature of the substrate W measured by the radiation thermometer 120 reaches the preheating temperature T1, the control unit 3 adjusts the output of the halogen lamps HL, and keeps the temperature of the substrate W at roughly the preheating temperature T1.

By performing such preheating by the halogen lamps HL, the temperature of the entire substrate W is uniformly increased to the preheating temperature T1. In the preheating stage of the halogen lamps HL, a temperature at the peripheral portion of the substrate W where heat is easily released tends to be reduced compared with a temperature at the center portion, but the density of the disposed halogen lamps HL of the halogen heating unit 4 is higher in the region facing the peripheral portion of the substrate W than in the region facing the center portion of the substrate W. Therefore, a larger amount of light is radiated on the peripheral portion of the substrate W where heat is easily released, and a uniform in-plane temperature distribution can be achieved for the substrate W in the preheating stage.

At a time point of lapse of a predetermined time after the temperature of the substrate W reaching the preheating temperature T1, the surface of the substrate W is irradiated with flash light from the flash lamps FL in the flash heating unit 5. At the time of flash light irradiation by the flash lamp FL, charge is accumulated in advance in the capacitor 93 by the power supply unit 95. Then, in a state where charge is accumulated in the capacitor 93, a pulse signal is output from the pulse generator 31 of the control unit 3 to the IGBT 96, and the IGBT 96 is turned on and off.

The waveform of the pulse signal can be defined by inputting, from the input unit 33, a recipe which has been sequentially set using parameters of a pulse width time (on time) and a pulse interval time (off time). When an operator inputs the above recipe from the input unit 33 to the control unit 3, the waveform setting unit 32 of the control unit 3 accordingly sets a pulse waveform that repeats on/off based on the recipe. Thus, the pulse generator 31 outputs a pulse signal based on the pulse waveform set by the waveform setting unit 32. As a result, the pulse signal having the set waveform is applied to the gate of the IGBT 96, and on/off driving of the IGBT 96 is thereby controlled. More specifically, when the pulse signal input to the gate of the IGBT 96 is on, the IGBT 96 is placed in an on-state, and when the pulse signal is off, the IGBT 96 is placed in an off-state.

In synchronization with the timing at which the pulse signal output from the pulse generator 31 becomes on, the control unit 3 controls the trigger circuit 97 and applies a high voltage (trigger voltage) to the trigger electrode 91. When the pulse signal is input to the gate of the IGBT 96 in a state where charge is accumulated in the capacitor 93, and a high voltage is applied to the trigger electrode 91 in synchronization with the timing at which the pulse signal becomes on, a current inevitably flows between the electrodes at both ends of the glass tube 92 while the pulse signal is on, and light is emitted due to excitation of atoms or molecules of xenon at that time.

Light is emitted from the 30 flash lamps FL in the flash heating unit 5 in the above manner, and the flash light is radiated on the front surface of the substrate W retained by the retention unit 7. Here, in a case where light is emitted from the flash lamps FL without using the IGBT 96, the charge accumulated in the capacitor 93 is consumed by one light emission, and an output waveform from the flash lamp FL becomes a simple single-pulse having a width of 0.1 milliseconds to 10 milliseconds. On the other hand, in the present preferred embodiment, the IGBT 96 serving as the switching element is connected in the circuit and the pulse signal is output to the gate of the IGBT 96, and charge is intermittently supplied from the capacitor 93 to the flash lamp FL by the IGBT 96, and on/off of the current flowing to the flash lamp FL is controlled. As a result, light emission of the flash lamp FL is controlled by chopper control, and charge accumulated in the capacitor 93 is divided and consumed and the flash lamp FL repeats blinking in an extremely short period of time. Additionally, before a value of current flowing in the circuit becomes completely “0”, the next pulse is applied to the gate of the IGBT 96 to increase the value of current again, and thus, a light emission output does not become completely “0” even while the flash lamp FL is repeating blinking.

By controlling on/off of the current flowing in the flash lamp FL by the IGBT 96, a light emission pattern of the flash lamp FL (time waveform of light emission output) can be freely defined, and thus, light emission time and light emission intensity can be freely adjusted. The pattern of on/off driving of the IGBT 96 is defined by the pulse width time and the pulse interval time input from the input unit 33. That is, when the IGBT 96 is incorporated in the drive circuit of the flash lamp FL, the light emission pattern of the flash lamp FL can be freely defined simply by appropriately setting the pulse width time and the pulse interval time input from the input unit 33.

More specifically, when a ratio of the pulse width time is increased with respect to the pulse interval time input from the input unit 33, the current flowing in the flash lamp FL is increased and the light emission intensity becomes strong. On the other hand, when the ratio of the pulse width time is reduced with respect to the pulse interval time input from the input unit 33, the current flowing in the flash lamp FL is reduced and the light emission intensity becomes weak. Furthermore, by appropriately adjusting the ratio of the pulse interval time and the pulse width time input from the input unit 33, the light emission intensity of the flash lamp FL can be maintained constant. Still further, when a total time of the combination of the pulse width time and the pulse interval time input from the input unit 33 is increased, the current keeps flowing to the flash lamp FL for a relatively long period of time, and the light emission time of the flash lamp FL is increased. The light emission time of the flash lamp FL is set between 0.1 milliseconds and 100 milliseconds, and in the present preferred embodiment, the time is set to 1.4 milliseconds.

Flash heating of the substrate W is thus performed by radiation of flash light on the front surface of the substrate W from the flash lamps FL over a radiation time of 1.4 milliseconds. Due to being irradiated with intense flash light over an extremely short radiation time of 1.4 milliseconds, the front surface of the substrate W including the hafnium oxide film 102 is instantaneously heated up to a treatment temperature T2. The treatment temperature T2, which is a maximum temperature (peak temperature) of the front surface of the substrate W reached by the flash light radiation, is at least 900° C., and in the present preferred embodiment, the temperature is 1100° C. In the flash heating, since the radiation time of the flash light is extremely short being 100 milliseconds or less, the front surface temperature of the substrate W drops to close to the preheating temperature T1 immediately after being instantaneously increased to the treatment temperature T2.

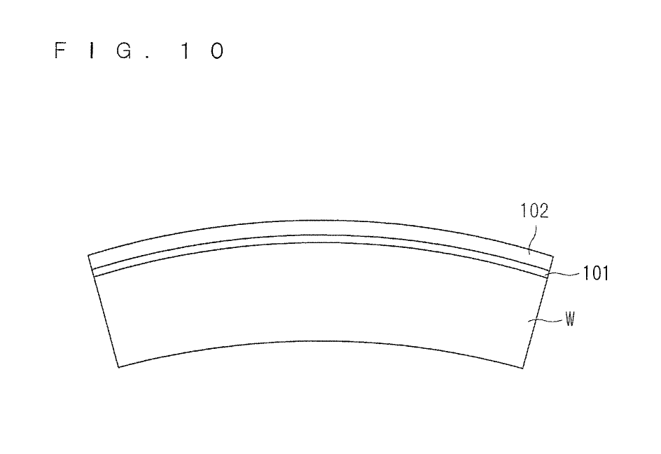

FIG. 10 is a view illustrating a behavior of the substrate W at the time of flash light radiation. The temperature of the front surface of the substrate W including the hafnium oxide film 102 is instantaneously increased up to the treatment temperature T2 (1100° C.) due to irradiation with intense flash light over an extremely short radiation time; however, the back surface of the substrate W is hardly increased from the preheating temperature T1 (500° C.). That is, a sharp temperature gradient instantaneously occurs from the front surface of the substrate W to the back surface. As a result, rapid thermal expansion occurs only at the front surface of the substrate W while thermal expansion hardly occurs at the back surface, and thus, as illustrated in FIG. 10, the substrate W is instantaneously curved with the front surface being caused to project. At this instant, under the condition of flash light radiation of the present preferred embodiment, a compressive stress of 570 MPa at the maximum is applied to the front surface of the substrate W, and a tensile stress of 140 MPa at the maximum is applied to the back surface of the substrate W.

The hafnium oxide film 102 formed on the front surface of the substrate W thus receives a compressive stress of 570 MPa at the maximum while being heated to the treatment temperature T2 by the flash light radiation. When the compressive stress is applied to the hafnium oxide film 102 heated to the treatment temperature T2, the hafnium oxide film 102 is caused to have a crystal structure.

Here, the hafnium oxide film 102 is caused to have a crystal structure also when the hafnium oxide film 102 is heated by rapid thermal annealing (RTA) in the same manner as the conventional post deposition annealing (PDA). The RTA is a heat treatment technique of increasing the temperature of a heating target object to a target temperature by radiation of light from a continuously lighting lamp, such as the halogen lamp, in a temperature rise time in units of seconds. The RTA is commonly a heat treatment technique of performing rapid heating, but the temperature rise speed is extremely slow compared with flash lamp annealing (FLA), which increases the temperature of a heating target object to a target temperature in units of milliseconds. Accordingly, in the case where the hafnium oxide film 102 is heated by the RTA, the hafnium oxide film 102 is simply heated, without occurrence of a compressive stress as in the case of flash light radiation described above.

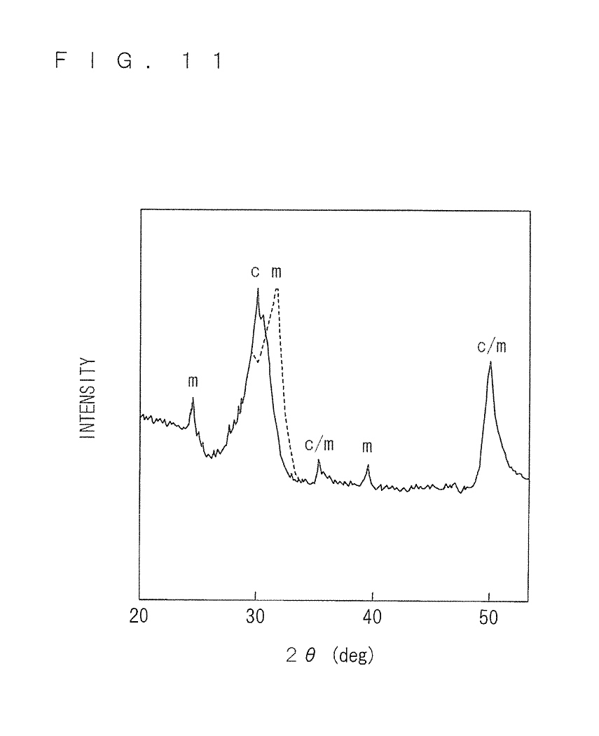

FIG. 11 is a view illustrating an X-ray diffraction pattern of the hafnium oxide film 102 after flash heating. In the drawing, an X-ray diffraction pattern of the hafnium oxide film 102 heated by the RTA is illustrated by a dotted line as a comparative example. Moreover, in FIG. 11, “c” indicates a peak of a cubic structure, and “m” indicates a peak of a monoclinic structure.

The hafnium oxide film 102 heated by flash light radiation and the hafnium oxide film 102 heated by the RTA both have a crystal structure where a cubic structure and a monoclinic structure are mixed. However, as illustrated in FIG. 11, a strong peak of the monoclinic structure appears with respect to the hafnium oxide film 102 heated by the RTA while a strong peak of the cubic structure appears with respect to the hafnium oxide film 102 heated by flash light radiation. This indicates that the proportion of cubic structure in the crystal structure is higher for the hafnium oxide film 102 heated by flash light radiation compared with the hafnium oxide film 102 heated by the RTA.

The reason the proportion of the cubic structure in the crystal structure is increased is considered to be that, when flash light radiation is performed, the hafnium oxide film 102 is heated and, at the same time, a strong compressive stress is applied to the hafnium oxide film 102, in contrast to the RTA according to which the hafnium oxide film 102 is simply heated. That is, by applying a strong compressive stress to the hafnium oxide film 102 at the same time as heating the hafnium oxide film 102 by flash light radiation, a chemical potential of the hafnium oxide film 102 is changed, and the proportion of the cubic structure with a higher filling factor (atomic packing factor) is increased compared with a case of heating by the RTA. The proportion of the cubic structure is desirably high in a case of using the hafnium oxide film 102 as a high-k dielectric gate insulating film of a field effect transistor.

After the flash heating treatment is ended, the halogen lamps HL are turned off after lapse of a predetermined period of time. The temperature of the substrate W thereby rapidly drops from the preheating temperature T 1. The temperature of the substrate W which is being dropped is measured by the radiation thermometer 120, and the measurement result is transmitted to the control unit 3. The control unit 3 monitors, based on the measurement result of the radiation thermometer 120, whether the temperature of the substrate W has dropped to a predetermined temperature. Then, after the temperature of the substrate W has dropped to a predetermined temperature or lower, the pair of transfer arms 11 of the transfer mechanism 10 is horizontally moved again from the retreat position to the transfer operation position and is raised, and the lift pins 12 protrude from the upper surface of the susceptor 74 to receive the substrate W after heat treatment from the susceptor 74. Subsequently, the conveyance opening portion 66 which was closed by the gate valve 185 is opened, and the substrate W placed on the lift pins 12 is carried out by the carrier robot outside the apparatus, and treatment of the substrate W by the heat treatment apparatus 1 is ended.

In the present preferred embodiment, the substrate W having the hafnium oxide film 102 formed on the front surface is heated to the predetermined preheating temperature T1, and then, flash heating is performed by irradiating the substrate W with flash light. Due to being irradiated with intense flash light over an extremely short radiation time, only the front surface of the substrate W including the hafnium oxide film 102 is instantaneously heated, and the hafnium oxide film 102 is heated to the treatment temperature T2 while a strong compressive stress is applied to the hafnium oxide film 102. As a result, compared with a case where the hafnium oxide film 102 is simply heated by the RTA, the proportion of the cubic structure in the crystal structure of the hafnium oxide film 102 after heat treatment may be increased. That is, by irradiating the front surface of the substrate W with the flash light from the flash lamps FL and heating the hafnium oxide film 102, and at the same time, applying a compressive stress to the hafnium oxide film 102, the crystal structure occurring in the hafnium oxide film 102 deposited on the substrate W can be adjusted.

By heating the hafnium oxide film 102 by flash light radiation, and applying a strong compressive stress to the hafnium oxide film 102, the proportion of the cubic structure with a high filling factor is increased, but the extent of increase is dependent on the magnitude of the applied compressive stress. The proportion of the cubic structure with a high filling factor is increased as the applied compressive stress is increased. Meanwhile, the magnitude of the compressive stress applied to the hafnium oxide film 102 is dependent on the radiation time of flash light radiated on the front surface of the substrate W. The amount of heat transfer from the front surface of the substrate W to the back surface is reduced and the temperature gradient is increased as the radiation time of flash light is reduced, and the compressive stress applied to the hafnium oxide film 102 is thereby increased. In the present preferred embodiment, the IGBT 96 is incorporated in the drive circuit of the flash lamp FL, and the radiation time of flash light can be adjusted based on the total time of the combination of the pulse width time and the pulse interval time input from the input unit 33. That is, by adjusting the radiation time of flash light based on the total time of the combination of the pulse width time and the pulse interval time input from the input unit 33, the magnitude of the compressive stress applied to the hafnium oxide film 102 can be changed and the proportion of the cubic structure with a high filling factor can be controlled. The compressive stress applied to the hafnium oxide film 102 is increased as the radiation time of flash light is reduced, and the proportion of the cubic structure in the crystal structure of the hafnium oxide film 102 can thus be increased.

Heretofore, the preferred embodiment of the present invention has been described, but various modifications may be made without departing from the scope of the present invention. For example, in the preferred embodiment described above, flash light is radiated on the substrate W having the hafnium oxide film 102 formed on the front surface, but this is not restrictive, and flash light may be radiated on a substrate W having a thin film of another material formed on the front surface, so as to control the crystal structure of the thin film. For example, flash light may be radiated on a substrate W having a silicon nitride thin film is formed on the front surface, so as to control the crystal structure of the thin film The etching rate of silicon nitride may be changed by adjusting the crystal structure of silicon nitride. Moreover, flash light may be radiated on a substrate W having a silicon dioxide thin film formed on the front surface, so as to control the crystal structure of the thin film.

In summary, the front surface of a substrate W having a thin film formed on the front surface may be irradiated with flash light from the flash lamp FL to heat the thin film, and a compressive stress may be applied to the thin film. By heating a thin film by flash light radiation, and applying a compressive stress to the thin film, the crystal structure occurring in the thin film may be adjusted such that the filling factor of crystal is increased.

Furthermore, the preheating temperature T1 and the treatment temperature T2 for the substrate W and the flash light radiation time of the flash lamp FL are not limited to the examples described in the preferred embodiment described above, and appropriate temperatures and time may be used. The compressive stress applied to the hafnium oxide film 102 may be changed not only by the flash light radiation time, but also by the preheating temperature T1 and the treatment temperature T2.

Moreover, in the preferred embodiment described above, 30 flash lamps FL are provided in the flash heating unit 5, but this is not restrictive, and an arbitrary number of flash lamps FL may be used. Also, the flash lamp FL is not limited to a xenon flash lamp, and may alternatively be a krypton flash lamp. Moreover, the number of halogen lamps HL provided in the halogen heating unit 4 is not limited to 40, and an arbitrary number of halogen lamps HL may be used.

In the aforementioned preferred embodiments, the filament-type halogen lamps HL are used as continuous lighting lamps that emit light continuously for not less than one second to heat the entire substrate W to preheating temperature T1. The present invention, however, is not limited to this. In place of the halogen lamps HL, arc lamps such as discharge type xenon arc lamps may be used as similar continuous lighting lamps to similarly heat the substrate W.

While the invention has been shown and described in detail, the foregoing description is in all aspects illustrative and not restrictive. It is therefore understood that numerous modifications and variations can be devised without departing from the scope of the invention.

What is claimed is:

1. A crystal structure control method for controlling a crystal structure of a thin film formed on a front surface of a substrate, the method comprising the steps of:
(a) depositing a thin film on a front surface of a substrate; and
(b) irradiating the front surface of said substrate with flash light from a flash lamp to heat said thin film and apply a compressive stress to said thin film.

2. The crystal structure control method according to claim 1, wherein
in said step (b), the compressive stress applied to said thin film is changed by adjusting a radiation time of said flash light.

3. The crystal structure control method according to claim 1, further comprising the step of:
(c) heating said substrate to a predetermined preheating temperature before said step (b).

4. A heat treatment method for heating a substrate having a thin film formed on a front surface, and for controlling a crystal structure of the thin film, wherein
flash light is radiated on the front surface of said substrate from a flash lamp to heat said thin film and apply a compressive stress to said thin film.
